(19) United States
(12) Patent Application Publication
(10) Pub. No.: US 2022/0300059 A1
(43) Pub. Date: Sep. 22, 2022

(54) INTERNET OF THINGS DEVICE AND BATTERY POWER DETECTION METHOD

(71) Applicant: Sercomm Corporation, Taipei (TW)

(72) Inventor: Kuo-Chuan Lin, Taipei (TW)

(73) Assignee: Sercomm Corporation, Taipei (TW)

(21) Appl. No.: 17/504,530

(22) Filed: Oct. 19, 2021

(30) Foreign Application Priority Data
Mar. 16, 2021 (CN) 202110281518.7

(51) Int. Cl. G06F 1/3212; G06F 1/3287; H04L 29/08

(52) U.S. Cl. CPC G06F 1/3212; G06F 1/3287; H04L 67/12

(57) ABSTRACT

The disclosure provides an internet of things (IoT) device and a battery power detection method. The IoT device includes a battery, an antenna, a radio frequency module, and a processor. The radio frequency module is configured to transmit or receive signals through the antenna, and the radio frequency module has a first power state and a second power state. The processor is configured to detect a first voltage of the battery corresponding to the first power state, detect a second voltage of the battery corresponding to the second power state, compare a voltage difference and a difference threshold between the first voltage and the second voltage, and determine that the battery is in a low battery state according to a comparison result. The first power state is power saving, standby, sleep, or off. The second power state is wake-up, operational, or normal.

### CROSS-REFERENCE TO RELATED APPLICATION

This application claims the priority benefit of Chinese application serial no. 202110281518.7, filed on Mar. 16, 2021. The entirety of the above-mentioned patent application is hereby incorporated by reference herein and made a part of this specification.

### BACKGROUND

### Technical Field

The disclosure relates to a power detection technology, and in particular to an Internet of Things device and a battery power detection method.

### Description of Related Art

Internet of Things (IoT) devices have the ability to transmit data over a network and can be used in areas such as transportation and logistics, industrial manufacturing, or smart environments. In some application contexts, Internet of Things devices may only be powered by batteries. For example, trackers of logistics routes, door and window opening and closing alarms, etc. It should be noted that while batteries can enhance mobility, Internet of Things devices will inevitably suffer from power depletion.

### SUMMARY

The disclosure is directed to an Internet of Things device and a battery power detection method, which detects a power state based on power characteristics of a battery, and detects a low battery state accordingly.

According to an embodiment of the disclosure, the Internet of Things device includes (but is not limited to) a battery, an antenna, a radio frequency module, and a processor. The radio frequency module is coupled to the battery and the antenna. The radio frequency module is configured to transmit or receive signals through the antenna, and the radio frequency module has a first power state and a second power state. The processor is coupled to the battery and the radio frequency module. The processor is configured to detect a first voltage of the battery corresponding to the radio frequency module operating in the first power state, detect a second voltage of the battery corresponding to the radio frequency module operating in the second power state, compare a voltage difference and a difference threshold between the first voltage and the second voltage, and determine that the battery is in a low battery state according to a comparison result. The first power state is power saving, standby, sleep, or off. The second power state is wake-up, operational, or normal.

According to an embodiment of the disclosure, the battery power detection method includes (but is not limited to) the following steps. A first voltage of a battery corresponding to a radio frequency module operating in a first power state is detected. A second voltage of the battery corresponding to the radio frequency module operating in a second power state is detected. A voltage difference and a difference threshold between the first voltage and the second voltage are compared, and that the battery is in a low battery state according to a comparison result is determined. The battery provides power to the radio frequency module. The first power state is power saving, standby, sleep, or off. The second power state is wake-up, operational, or normal.

Based on the above, in the Internet of Things device and the battery power detection method according to the embodiment of the disclosure, the first voltage (e.g., a highest voltage) and the second voltage (e.g., a lowest voltage) of the Internet of Things device are observed during a complete report event cycle (from hibernate to wake-up to report event to hibernate, which occurs periodically), and a battery state is inferred based on the voltage difference between the two. Thus, a battery voltage is monitored for a short period of time to determine the battery state.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a block diagram showing a component layout of an Internet of Things device according to an embodiment of the disclosure.

FIG. 2 is a flowchart of a battery power detection method according to an embodiment of the disclosure.

FIG. 3 shows a discharge curve of a battery according to an embodiment of the disclosure.

FIG. 4 is a flowchart of a battery power detection method according to an embodiment of the disclosure.

### DESCRIPTION OF THE EMBODIMENTS

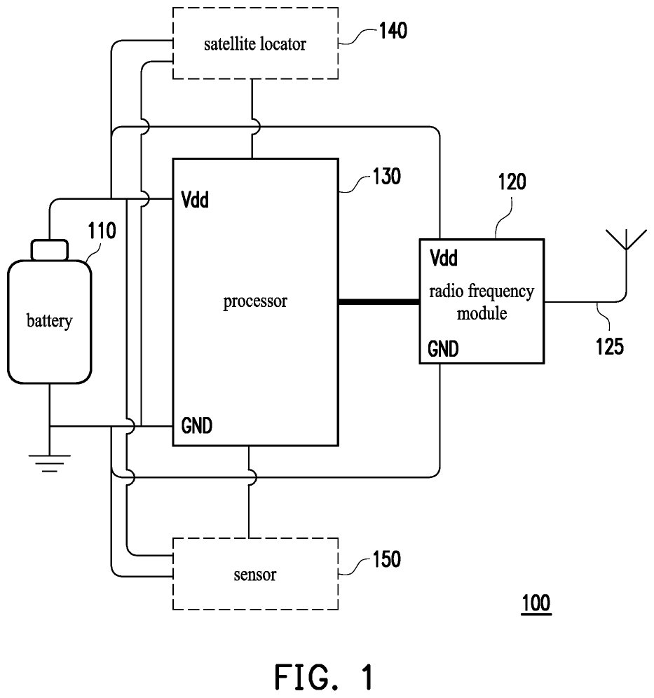

FIG. 1 is a block diagram showing a component layout of an Internet of Things device 100 according to an embodiment of the disclosure. The Internet of Things device 100 includes (but is not limited to) a battery 110, a radio frequency module 120, an antenna 125, and a processor 130. The Internet of Things device 100 is, for example, a locator, a tracker, a sensor, a wearable device, a health monitoring device, a remote monitoring device, a smart smoke alarm, a production process monitoring device, etc., and is not limited thereto.

The battery 110 is, for example, a carbon-zinc battery, an alkaline manganese battery, a lithium battery, other disposable batteries (primary batteries), a lithium ion battery, a nickel-hydrogen battery, a nickel-cadmium battery, or other rechargeable batteries (also known as secondary batteries). The battery 110 is configured to provide power to all or part of the components of the Internet of Things device 100.

The radio frequency module 120 is coupled to the battery 110 and the antenna 125 to receive power from the battery 110. The radio frequency module 120 supports, for example, a low-power wide-area network (LPWAN), fourth-generation or fifth-generation mobile communication, Z-Wave, Wi-Fi, Bluetooth mesh network, or other wireless communication technology. The radio frequency module 120 is configured to transmit or receive signals through the antenna 125. It should be noted that, without being limited to the antenna 125, the radio frequency module 120 also includes, for example, a digital-to-analog converter, an analog-to-digital converter, and a communication protocol processor, depending on actual requirements.

The processor 130 is coupled to the battery 110 to receive power from the battery 110. In addition, the processor 130 is coupled to the radio frequency module 120. The processor 130 may be implemented, for example, by a programmable unit such as a central processing unit (CPU), a microprocessor, a microcontroller, a digital signal processing (DSP) chip, a field programmable logic gate array (FPGA), or a standalone electronic device or integrated circuit (IC).

According to an embodiment, the Internet of Things device 100 further includes a satellite locator 140, such as one that supports the Global Positioning System (GPS), BeiDou satellite navigation system, Galileo positioning system, or other satellite-based positioning system.

According to an embodiment, the Internet of Things device 100 further includes a sensor 150. The sensor 150 may be a detection device for light, heat, gas, force, magnetism, humidity, liquid, sound, or other sensory characteristics.

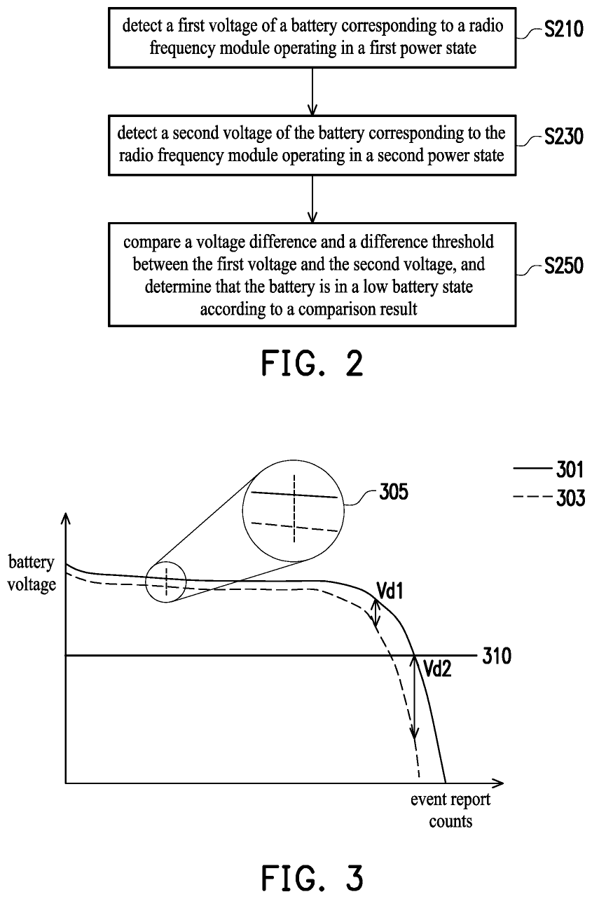

FIG. 2 is a flowchart of a battery power detection method according to an embodiment of the disclosure. The processor 130 may detect a first voltage of a battery corresponding to the radio frequency module 120 operating in a first power state (step S210). Specifically, the radio frequency module 120 has two power states. The first power state is power saving, standby, sleep, or off. A second power state is wake-up, operational, or normal, and power consumption of the second power state is even greater than the first power state. For example, a period of transmission after waking up in the power saving state is even longer compared to the normal state. Another example is that during the off state, the radio frequency module 120 does not receive or transmit signals.

When the radio frequency module 120 is in the first power state, the processor 130 may measure a power voltage Vdd (assuming that the battery 110 is connected to ground GND) to know a current voltage of the battery 110 (as the first voltage). According to some embodiments, the processor 130 monitors the power voltage Vdd, and takes a highest value, a lowest value, an average value, or other representative value measured by the processor 130 during a period when the radio frequency module 120 operates at the first power state as the first voltage. It should be noted that the processor 130 may provide a pin to connect to the battery 110 (i.e., measure a voltage directly with a built-in analog-to-digital converter), or may detect the voltage of the battery 100 through an external voltage detection circuit (not shown).

The processor 130 may detect a second voltage of the battery corresponding to the radio frequency module 120 operating in the second power state (step S230). Specifically, the processor 130 may control the radio frequency module 120 switching from the first power state to the second power state. For example, the processor 130 starts the power of the radio frequency module 120 to switch from the off state to the normal state, or to wake up the frequency module 120 from the power saving/sleep state.

When the radio frequency module 120 is in the second power state, the processor 130 may measure the power voltage Vdd to know the current voltage of the battery 110 (as the second voltage). In other words, the first voltage and the second voltage are the battery voltages detected by the processor 130 while the radio frequency module 120 operating in different power states. According to some embodiments, the processor 130 monitors the power voltage Vdd, and takes a highest voltage, a lowest voltage, an average voltage, or other representative voltage measured by the processor 130 during a period when the radio frequency module 120 operates at the second power state as the second voltage.

According to some embodiments, when the radio frequency module 120 is in the second power state, the radio frequency module 120 may report status or events through the antenna 125. The status or events may originate from the processor 130, the satellite locator 140, or the sensor 150, for example, based on abnormalities or states of the device detected by the processor 130, location information provided by the satellite locator 140, or sensing results detected by the sensor 150.

The processor 130 may compare a voltage difference and a difference threshold between the first voltage and the second voltage, and determine that the battery is in a low battery state according to a comparison result (step S250). FIG. 3 shows a discharge curve of a battery according to an embodiment of the disclosure. The battery 110 has characteristics of different voltage drops during an event report cycle. The voltage drop is a difference between a voltage at a higher load (e.g., the lower voltage) and a voltage at a lower load (e.g., the higher voltage) detected by the battery 110 during the event report cycle (hereinafter referred to as the voltage difference). From partial amplification 305, a difference in voltage may be measured in a same time interval or with a same number of reports, as shown in curve 301 and curve 303. It should be noted that when the battery 110 is in a low battery state (e.g., voltage below a voltage threshold 310), the voltage difference expands dramatically. For example, a voltage difference Vd1 corresponding to a case where the battery voltage is above the voltage threshold 310 is smaller than a voltage difference Vd2 corresponding to a case where the battery voltage is below the voltage threshold 310. Different power states of the radio frequency module 120 will result in different voltage readings for the battery 110. It can be seen that, based on the voltage difference of the radio frequency module 120 in different power states, whether the battery 110 is in the low battery state may also be inferred. The low battery state may be that the power is below a corresponding threshold, or the remaining time of power available to the component is below a corresponding threshold, but not limited thereto.

The processor 130 may set a difference threshold to be used as a baseline for determining the low battery state. In response to the voltage difference between the first voltage and the second voltage being less than the difference threshold, the processor 130 may determine that the battery 110 is not yet in a low battery state. In response to the voltage difference being greater than or equal to the difference threshold, the processor 130 may determine that the battery 110 is in a low battery state. The voltage difference is, for example, a value obtained by subtracting the second voltage from the first voltage.

According to an embodiment, in response to detecting that the battery 110 is in a low battery state, the processor 130 may report events related to the low battery state through the radio frequency module 120.

According to an embodiment, the processor 130 may accumulate a number of times the battery 110 is judged to be in a low battery state. For example, in response to detecting that the battery 110 is in a low battery state, the number of times recorded by a counter plus one. The processor 130 may determine that the battery 110 is in a low battery state according to the number of times. In order to avoid misjudgment of the low battery state caused by sudden abnormal power consumption, the processor 130 may accumulate a specific number of times before determining the battery 110 as low battery state. For example, in response to an accumulated number of times greater than a count threshold, the processor 130 then determines that the battery 110 is in a low battery state. In response to the accumulated number of times not being greater than the count threshold, the processor 130 determines that the battery 110 is still not in a low battery state. According to some embodiments, the number of times needs to be accumulated continuously, otherwise the processor 130 will recount.

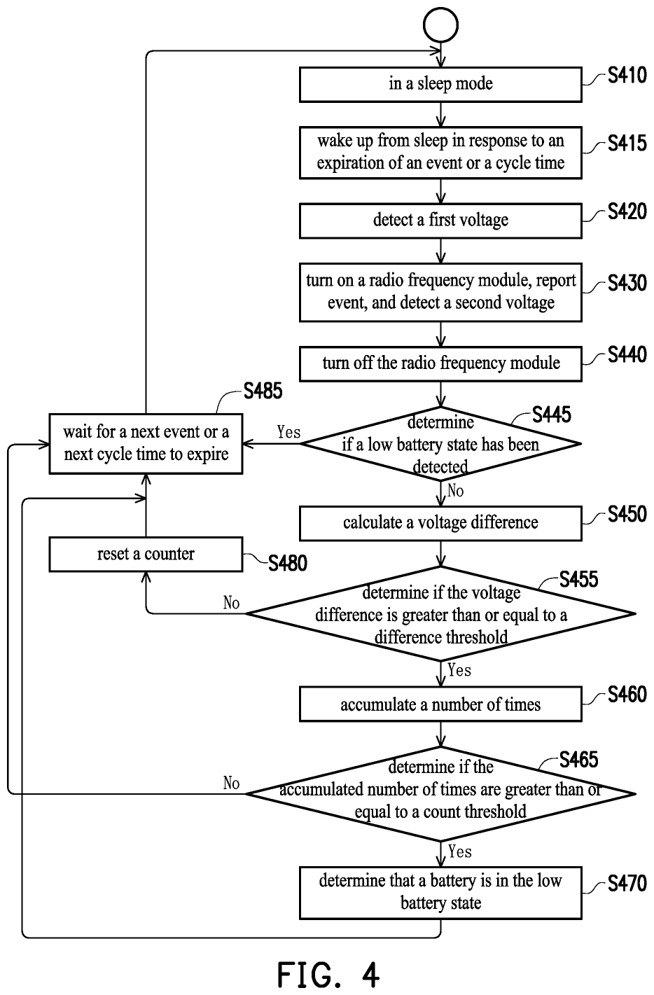

FIG. 4 is a flowchart of a battery power detection method according to an embodiment of the disclosure. It is assumed that the processor 130 reports events through the radio frequency module 120 at regular intervals or in response to event triggers. For example, a tracker reports a position at regular intervals, and an access detector detects whether a door is open or not. The processor 130 is in a hibernation mode (or a sleep mode) (step S410). In response to an expiration of an event or a cycle time, the processor 130 wakes up from the sleep mode (step S415). The events may be triggered based on the sensing results detected by the sensor 150 or generated by other factors. The cycle time may be a period for regularly reporting the position, state, or mode. On the other hand, the radio frequency module 120 is in the first power state, and the processor 130 detects the first voltage (step S420). After that, the processor 130 turns on the radio frequency module 120, so that the radio frequency module 120 switches from the first power state to the second power state. The processor 130 reports the events through the radio frequency module 120. For example, the Internet of Things device 100 transmits the location information, status, or sensing results. In addition, the processor 130 monitors the battery voltage when the radio frequency module 120 is in the second power state, and detects the second voltage (step S430). For example, the processor 130 obtains the battery voltage before/in/after the radio frequency module 120 reports, and the processor 130 compares the battery voltage in the second power state and obtains the lowest voltage as the second voltage. After that, the processor 130 turns off the radio frequency module 120, so that the radio frequency module 120 switches from the second power state to the first power state (step S440).

The processor 130 determines whether the battery 110 has been detected as low battery state (step S445). In response to not yet detecting the low battery state, the processor 130 calculates the voltage difference between the first voltage and the second voltage (step S450), and determines whether the voltage difference is greater than or equal to the difference threshold (step S455).

In response to the voltage difference greater than or equal to the difference threshold, the processor 130 accumulates the number of times (step S460). The processor 130 determines whether the accumulated number of times is greater than or equal to the count threshold (step S465). In response to the accumulated number of times greater than or equal to the count threshold, the processor 130 determines that the battery 110 is in a low battery state (step S470).

In response to the voltage difference being less than the difference threshold or the accumulated number of times being less than the count threshold, the processor 130 resets the counter (i.e., the number of times is zeroed) (step S480). In addition, in response to having detected that the battery 110 is in a low battery state, the accumulated number of times is less than the count threshold, or the counter is reset, the processor 130 enters hibernation mode and waits for a next event or a next cycle time to expire (step S485).

In summary, the Internet of Things device and the battery power detection method according to the embodiments of the disclosure may monitor the battery voltage of the radio frequency module in two power states, and determine the low battery state based on the voltage difference between the two voltages. According to the embodiments of the disclosure, the first voltage and the second voltage are detected by reading the battery voltage directly from the processor, without the need for additional hardware circuitry, and a software algorithm is provided to determine whether the battery is in a low battery state. The first voltage and the second voltage are determined by observing the highest voltage and the lowest voltage of the Internet of Things device during a complete report event cycle (e.g., from hibernate to wake-up to report event to hibernate, which occurs periodically). For example, the highest voltage is the first voltage, and the lowest voltage is the second voltage, and the low battery state is determined by the difference between the two voltages according to this embodiment. In this way, the low battery state may be quickly determined during an operation of the Internet of Things device, so that the personnel concerned may replace the battery earlier or at the right time.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An Internet of Things device comprising:
a battery;
an antenna;
a radio frequency module coupled to the battery and the antenna, transmitting or receiving signals through the antenna, and having a first power state and a second power state; and
a processor coupled to the battery and the radio frequency module, and configured to:
detect a first voltage of the battery corresponding to the radio frequency module operating in the first power state, wherein the first power state is power saving, standby, sleep, or off;
detect a second voltage of the battery corresponding to the radio frequency module operating in the second power state, wherein the second power state is wake-up, operational, or normal; and
compare a voltage difference and a difference threshold between the first voltage and the second voltage, and determine that the battery is in a low battery state according to a comparison result.

2. The Internet of Things device according to claim 1, wherein
in response to an expiration of an event or a cycle time, the processor wakes up from a hibernation mode, and the processor detects the first voltage.

3. The Internet of Things device according to claim 2 further comprising:
a satellite locator coupled to the battery and the processor, and configured to provide location information to the processor, wherein the processor is further configured to transmit the location information through the radio frequency module.

4. The Internet of Things device according to claim 2 further comprising:
a sensor coupled to the battery and the processor, and configured to generate the event according to a sensing result.

5. The Internet of Things device according to claim 2, wherein
in response to the processor detecting the first voltage, the processor is further configured to control the radio frequency module switching from the first power state to the second power state.

6. The Internet of Things device according to claim 1, wherein the processor is further configured to:
obtain a lowest voltage of the battery detected in the second power state as the second voltage.

7. The Internet of Things device according to claim 1, wherein the processor is further configured to:
accumulate a number of times the battery is judged to be in the low battery state; and
determine that the battery is in the low battery state according to the number of times.

8. A battery power detection method comprising:
detecting a first voltage of a battery corresponding to a radio frequency module operating in a first power state, wherein the first power state is a power saving, standby, sleep, or off, and the battery provides power to the radio frequency module;
detecting a second voltage of the battery corresponding to the radio frequency module operating in a second power state, wherein the second power state is wake-up, operational, or normal; and
comparing a voltage difference and a difference threshold between the first voltage and the second voltage, and determining that the battery is in a low battery state according to a comparison result.

9. The battery power detection method according to claim 8, wherein detecting the second voltage of the battery corresponding to the radio frequency module operating in the second power state comprises:
in response to an expiration of an event or a cycle time, waking up from a hibernation mode, and detecting the first voltage.

10. The battery power detection method according to claim 9 further comprising:
transmitting location information through the radio frequency module.

11. The battery power detection method according to claim 9 further comprising:
generating the event according to a sensing result of a sensor.

12. The battery power detection method according to claim 9, wherein after detecting the first voltage of the battery corresponding to the radio frequency module operation in the first power state further comprises:
in response to detecting the first voltage, controlling the radio frequency module switching from the first power state to the second power state.

13. The battery power detection method according to claim 8, wherein detecting the second voltage of the battery corresponding to the radio frequency module operating in the second power state comprises:
obtaining a lowest voltage of the battery detected in the second power state as the second voltage.

14. The battery power detection method according to claim 8, wherein determining that the battery is in the low battery state further comprises:
accumulating a number of times the battery is judged to be in the low battery state; and
determining that the battery is in the low battery state according to the number of times.
